(19) United States
(12) Patent Application Publication
(10) Pub. No.: US 2015/0243231 A1
(43) Pub. Date: Aug. 27, 2015

(54) DISPLAY DEVICE AND ELECTRONIC APPARATUS

(71) Applicant: Sony Corporation, Tokyo (JP)

(72) Inventor: Mikihiro Yokozeki, Kanagawa (JP)

(21) Appl. No.: 14/615,007

(22) Filed: Feb. 5, 2015

(30) Foreign Application Priority Data
Feb. 24, 2014 (JP) 2014-032851

(51) Int. Cl. G09G 3/36

(52) U.S. Cl. CPC G09G 3/3607; G09G 2320/0233; G09G 2300/0426; G09G 2300/0434

(57) ABSTRACT

Disclosed is a display device including a display element and a transistor configured to drive the display element. The transistor has a channel layer, a gate electrode laminated under the channel layer, and wiring connecting the gate electrode and a capacitance electrode together. The capacitance electrode and the wiring are made of at least a transparent material.

### CROSS REFERENCE TO RELATED APPLICATIONS

This application claims the benefit of Japanese Priority Patent Application JP2014-032851 filed Feb. 24, 2014, the entire contents of which are incorporated herein by reference.

### BACKGROUND

The present technology relates to display devices and electronic apparatuses. Specifically, the present technology relates to a display device desirably applied to a device called a transparent display or the like and relates to an electronic apparatus.

In recent years, displays called transparent displays or the like have become widespread. A transparent display is a display in which the backlight of a liquid crystal panel is, for example, removed to allow the visual recognition of its back surface side.

On the other hand, AR (Augmented Reality) technology has been frequently discussed. The AR technology features the presentation of a virtual object as additional information (electronic information) in combination with (a part of) real environment and is contrasted with virtual reality (VR). In the AR technology, it is general that an explanation or related information on a specific object in real environment is presented near the actual object as an explanation object. Thus, in order to achieve the AR, technology for acquiring information on real environment such as a location at which a user observes an object has been seriously taken as base technology.

As a method for enhancing reality (sense of reality) in the AR, it has been proposed to use a transparent display (see, for example, Japanese Patent Application Laid-open No. 2012-238544).

### SUMMARY

In principle, there is a difficulty in improving the transmittance of a transparent display in which the backlight of a liquid crystal is removed. A reason for it is that the liquid crystal outputs an image with the adjustment of the light transmission amount of the backlight. Therefore, holes are made in a part other than the liquid crystal to improve transmittance. However, if the holes are made excessively, an image is hardly seen.

In addition, since the liquid crystal is not self-luminous device, an image is hardly seen under a dark background. For example, if there is an item on the back surface side of the transparent display in a case in which the transparent display is used in a shop window or the like, an image at the area may be hardly seen.

From the above reasons, it is desirable to improve the transmittance of a transparent display.

The present technology has been made in view of the above circumstances, and it is therefore desirable to provide a display that improves transmittance.

An embodiment of the present technology provides a display device including a display element and a transistor configured to drive the display element. The transistor has a channel layer, a gate electrode laminated under the channel layer, and wiring connecting the gate electrode and a capacitance electrode together. The capacitance electrode and the wiring are made of at least a transparent material.

The gate electrode, the capacitance electrode, and the wiring may be made of the same transparent material.

The transparent material may include an amorphous-based material.

The transparent material may include a crystal-based material.

The gate electrode may be made of metal, the capacitance electrode and the wiring may be made of the transparent material, and the wiring may be laminated between the gate electrode and the channel layer. The wiring may be connected to the gate electrode so as to cover an upper surface of the gate electrode.

The gate electrode may be made of metal, the capacitance electrode and the wiring may be made of the transparent material, and the wiring may be formed on a lower surface of the gate electrode.

The wiring may be connected to the gate electrode so as to cover the lower surface of the gate electrode.

A light-shielding film may be laminated on an upper side of the channel layer.

The display device may further include a gate electrode on an upper side of the channel layer. The channel layer may be made of a transparent material.

The display element may include an organic EL (Electro Luminescence) element.

The transistor may include a TFT (Thin Film Transistor).

Another embodiment of the present technology provides an electronic apparatus including a display device. The display device has a display element and a transistor configured to drive the display element. The transistor has a channel layer, a gate electrode laminated under the channel layer, and wiring connecting the gate electrode and a capacitance electrode together. The capacitance electrode and the wiring are made of at least a transparent material.

A display device according to an embodiment of the present technology includes a display element and a transistor configured to drive the display element. The transistor has a channel layer, a gate electrode laminated under the channel layer, and wiring connecting the gate electrode and a capacitance electrode together. The capacitance electrode and the wiring are made of at least a transparent material.

According to an embodiment of the present technology, it becomes possible to provide a display that improves transmittance.

Note that the above effects are only for illustration and any effect described in the present disclosure may be produced.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a diagram showing the configuration of an embodiment of a display device to which the present technology is applied;

FIG. 2 is a circuit diagram showing the configuration of a pixel;

FIG. 3 is a view showing the configuration of a TFT;

FIGS. 4A and 4B are views for describing a transmission region;

FIG. 5 is a view showing the configuration of a TFT;

FIGS. 6A and 6B are views for describing a transmission region;

FIG. 7 is a view for describing a transmission region;

FIG. 8 is a view showing the configuration of a TFT;

FIGS. 9A and 9B are views for describing a transmission region;

FIG. 10 is a view for describing a transmission region;

FIG. 11 is a view showing the configuration of a TFT;

FIGS. 12A and 12B are views for describing a transmission region;

FIG. 13 is a view showing the configuration of a TFT;

FIGS. 14A and 14B are views for describing a transmission region;

FIG. 15 is a view showing the configuration of a TFT;

FIGS. 16A and 16B are views for describing a transmission region;

FIG. 17 is a view showing the configuration of a TFT;

FIGS. 18A and 18B are views for describing a transmission region;

FIGS. 19A and 19B are graphs for describing influence by roughness occurring at a front surface;

FIG. 20 is a view showing the configuration of a TFT;

FIGS. 21A and 21B are views for describing a transmission region;

FIG. 22 is a view showing the configuration of a TFT;

FIG. 23 is a view showing the configuration of a TFT;

FIG. 24 is a view for describing an application example of the present technology;

FIG. 25 is a view for describing an application example of the present technology;

FIG. 26 is a view for describing an application example of the present technology; and

FIG. 27 is a view for describing an application example of the present technology.

### DETAILED DESCRIPTION OF EMBODIMENTS

Hereinafter, modes (hereinafter called embodiments) for carrying out the present technology will be described. Note that the description will be given in the following order.

### 1. Configuration of Display Device

### 2. Configuration of Pixel

### 3. Conditions for Improving Transmittance

### 4. First Embodiment

### 5. Second Embodiment

### 6. Third Embodiment

### 7. Application Examples

(Configuration of Display Apparatus)

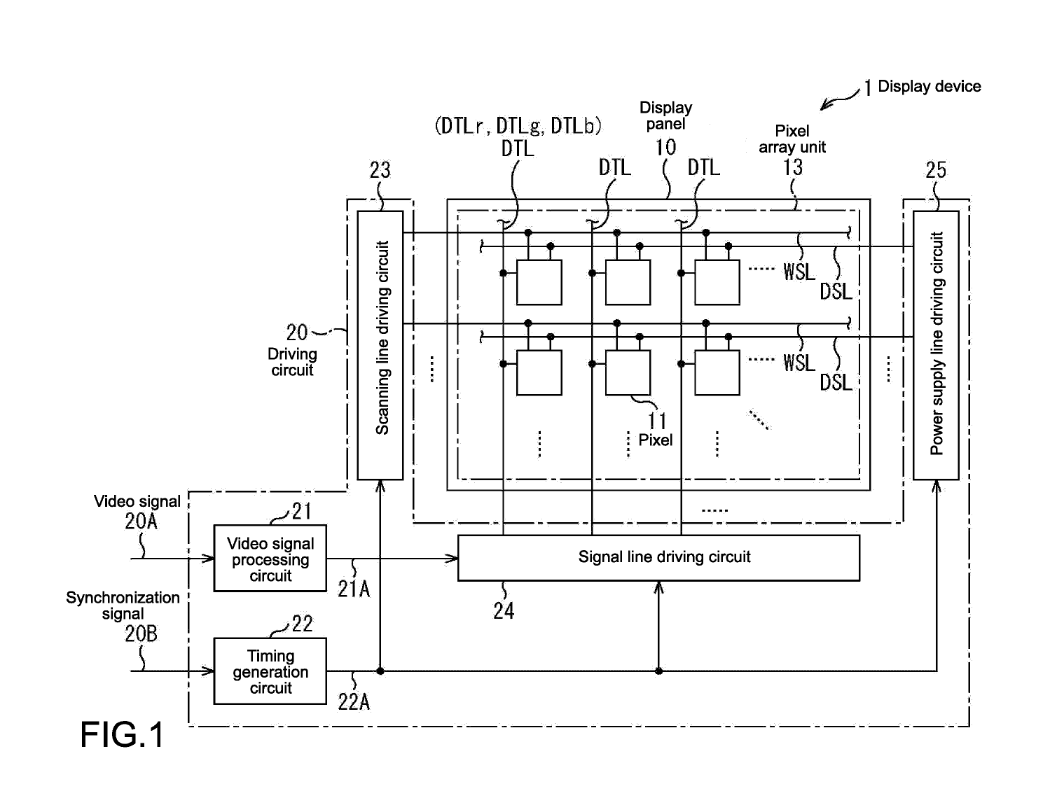

FIG. 1 is a diagram showing the configuration of an embodiment of a display device to which the present technology is applied. The display device 1 shown in FIG. 1 has a display panel 10 and a driving circuit 20 and allows the visual recognition of its back surface side with at least a part of pixels as a light transmittance region (transparent region) as will be described later. Such a display (display device) allowing the visual recognition of its back surface side is a so-called transparent display or the like.

The display panel 10 has a pixel array unit 13 in which a plurality of pixels 11 are arranged in a matrix pattern and performs image display by active matrix driving based on a video signal 20A and a synchronization signal 20B input from an outside. The respective pixels 11 include a plurality of sub-pixels (sub-pixels for respective colors) corresponding to a plurality of colors, for example, the three colors of RGB (Red, Green, and Blue).

The pixel array unit 13 has a plurality of scanning lines WSL arranged in a row pattern, a plurality of signal lines DTL arranged in a column pattern, and a plurality of power supply lines DSL arranged in a row pattern along the scanning lines WSL. Each of the scanning lines WSL, the signal lines DTL, and the power supply lines DSL has one end thereof connected to a driving circuit 20 that will be described later. In addition, the above respective pixels 11 are arranged in a matrix pattern so as to correspond to the intersections between the respective scanning lines WSL and the respective signal lines DTL. Note that in FIG. 1, a plurality of signal lines (signal lines for the respective colors) DTLr, DTLg, and DTLb corresponding to the plurality of colors are simply shown as the signal lines DTL.

The driving circuit 20 drives the pixel array unit 13 (the display panel 10). Specifically, the driving circuit 20 writes, while successively selecting the plurality of pixels 11 in the pixel array unit 13, a video signal voltage based on the video signal 20A in the respective sub-pixels of the selected pixels 11 to perform display driving on the plurality of pixels 11. That is, the driving circuit 20 performs the display driving on the respective sub-pixels based on the video signal 20A.

The driving circuit 20 has a video signal processing circuit 21, a timing generation circuit 22, a scanning line driving circuit 23, a signal line driving circuit 24, and a power supply line driving circuit 25.

The video signal processing circuit 21 performs prescribed video signal processing on the digital video signal 20A input from the outside and outputs a video signal 21A subjected to the video signal processing to the signal line driving circuit 24. Examples of the prescribed video signal processing include gamma correction processing and overdrive processing.

The timing generation circuit 22 generates and outputs a control signal 22A based on the synchronization signal 20B input from the outside to make the scanning line driving circuit 23, the signal line driving circuit 24, and the power supply line driving circuit 25 operate together.

The scanning line driving circuit 23 successively applies a selection pulse to the plurality of scanning lines WSL according to (in synchronization with) the control signal 22A to successively select the plurality of pixels 11. Specifically, the scanning line driving circuit 23 generates the above selection pulse in such a way as to selectively output a voltage Von applied when a writing transistor Tr1 is turned ON and a voltage Voff applied when the writing transistor Tr1 is turned OFF. Here, the voltage Von is set at a value (constant value) greater than or equal to the ON-voltage of the writing transistor Tr1, and the voltage Voff is set at a value (constant value) less than or equal to the ON-voltage of the writing transistor Tr1.

The signal line driving circuit 24 generates an analog video signal corresponding to the video signal 21A input from the video signal processing circuit 21 according to (in synchronization with) the control signal 22A and applies the same to the respective signal lines DTL (DTLr, DTLg, and DTLb). Specifically, the signal line driving circuit 24 separately applies an analog video signal voltage for the respective colors based on the video signal 21A to the respective signal lines DTLr, DTLg, and DTLb. Thus, the signal line driving circuit 24 writes the video signal in the respective sub-pixels of the pixels 11 selected by the scanning line driving circuit 23.

The power supply line driving circuit 25 successively applies a control pulse to the plurality of power supply lines DSL according to (in synchronization with) the control signal 22A to control the luminescence (lighting) operation and the non-luminescence (extinction or shutoff) operation of organic EL (Electro Luminescence) elements 12 in the respective sub-pixels of the respective pixels 11. In other words, the power supply line driving circuit 25 adjusts the width (pulse width) of the control pulse to control the lengths of a luminescence period and a non-luminescence period (extinction period) in the respective sub-pixels of the respective pixels 11.

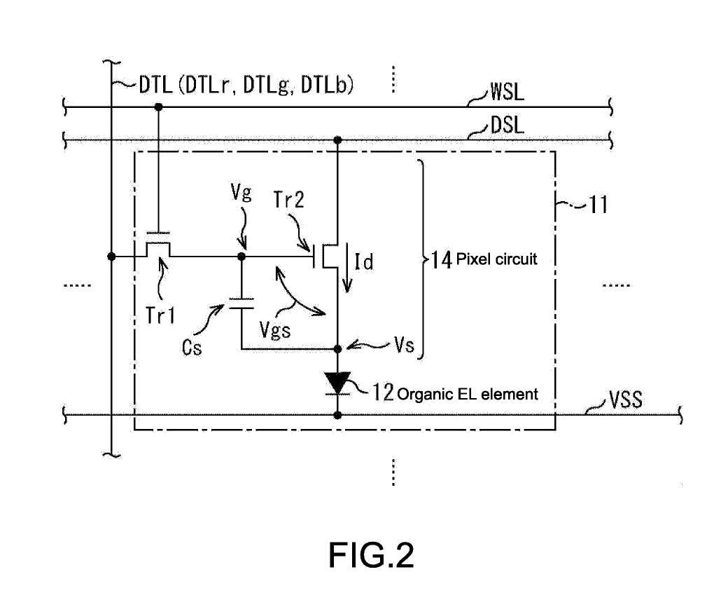

FIG. 2 is a diagram showing an example of the internal configuration (circuit configuration) of the respective sub-pixels. Note that in the following description, the sub-pixels will be called pixels. In the respective pixels, the organic EL element 12 (luminescence element) and a pixel circuit 14 are provided.

The pixel circuit 14 has a writing (sampling) transistor Tr1, a driving transistor Tr2, and a retention capacitance element Cs. That is, the pixel circuit 14 has a so-called “2Tr1C” circuit configuration.

Note that although the “2Tr1C” circuit configuration will be described as an example, the application of the present technology described below is not limited to the “2Tr1C” circuit configuration. That is, the present technology may also be applied to a display device having a circuit configuration other than the “2Tr1C” circuit configuration.

Here, each of the writing transistor Tr1 and the driving transistor Tr2 is made of, for example, an n-channel MOS (Metal Oxide Semiconductor) TFT (Thin Film Transistor). Note that the type of a TFT to which the present technology is applied is not particularly limited but any TFT other than the TFT shown here may also be used.

In the pixel circuit 14, the gate of the writing transistor Tr1 is connected to the scanning line WSL, the drain thereof is connected to the signal line DTL (DTLr, DTLg, and DTLb), and the source thereof is connected to the gate of the driving transistor Tr2 and one end of the retention capacitance element Cs. The drain of the driving transistor Tr2 is connected to the power supply line DSL and the source thereof is connected to the other end of the retention capacitance element Cs and the anode of the organic EL element 12. The cathode of the organic EL element 12 is set at, for example, fixed potential VSS (for example, ground potential) on wiring extending along the direction of a horizontal line.

(Configuration of Pixel)

In addition, a description will be next given of the configuration of the pixel. The pixel of the embodiment is such that at least a part of the pixel forms a region that allows the transmission of light. As will be described in detail later, at least one of the semiconductor layer, the electrode layer, and the wiring layer of the driving elements (the writing transistor Tr1, the driving transistor Tr2, and the retention capacitance element Cs) is made of a light transmission material (transparent material) in the pixel circuit 14 of the pixel 11.

Thus, the pixel 11 is allowed to show a high aperture ratio. With a high aperture ratio, it becomes possible to improve light transmittance and achieve the display device 1 that allows the visual recognition of its back surface side.

For the display device 1 that allows the visual recognition of its back surface side, an improvement in light transmittance is desirable. In order to explain this or clarify the difference between the embodiment and the related art, a description will be first given of the configuration of a TFT used in a general pixel.

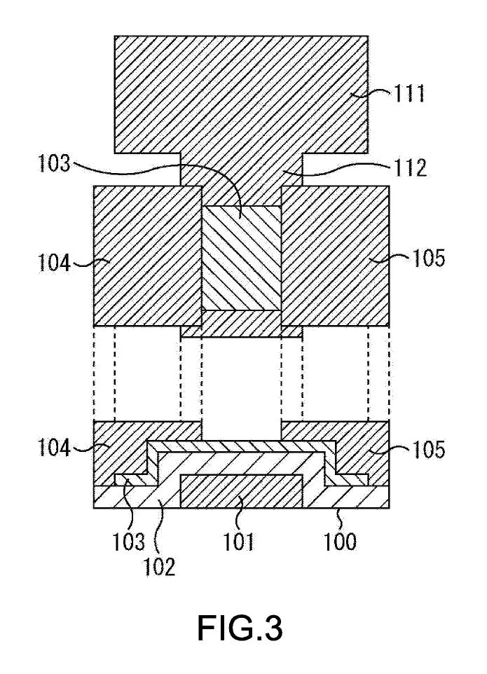

FIG. 3 is a view showing the configuration of an example of a non-transmittance TFT. The upper side of FIG. 3 is a plan view of the TFT when seen from the above, and the lower side thereof is a cross-sectional view corresponding to the plan view.

Referring to the cross-sectional view of the TFT shown on the lower side, a substrate is formed on the lowermost part of the TFT 100 and an insulation film is formed on the substrate although they are not shown in FIG. 3. In addition, a gate electrode 101 and a gate insulation film 102 are formed on the insulation film. A channel layer 103 is formed on the gate insulation film 102. A source electrode 104 is formed on the upper left side of the channel layer 103, and a drain electrode 105 is formed on the upper right side thereof.

The substrate (not shown) is, for example, a glass substrate but may be made of other material such as synthetic quartz, a resin, and a resin film. The insulation film is made of, for example, an insulation film material containing silicon (Si).

The gate electrode 101 controls carrier density (here, electron density) in the channel part of the channel layer 103 with a gate voltage applied to the TFT 100. Like the above insulation film, the gate insulation film 102 is made of, for example, an insulation film material containing silicon. The gate insulation film 102 covers the gate electrode 101 and is formed over, for example, the entire front surface of the substrate including the gate electrode 101.

A channel protection film (not shown) made of, for example, the same material as the above insulation film is formed at a region opposing the gate electrode 101 on the channel layer 103. A pair of the source electrode 104 and the drain electrode 105 is formed at a region ranging from the front surface of the channel protection film to the front surface of the channel layer 103.

Each of the source electrode 104 and the drain electrode 105 is made of, for example, metal such as molybdenum, aluminum, and titanium or a multilayer film made of these substances.

Note that a protection film (passivation film) made of, for example, the same material as the insulation film may be formed on the source electrode 104 and the drain electrode 105 although it is not shown in FIG. 3.

When seen from the above, the TFT 100 having such a configuration may be expressed by the plan view as shown on the upper side of FIG. 3. When the TFT 100 is seen from the above, a part of the channel layer 103 is located on the gate electrode 101 and the source electrode 104 and the drain electrode 105 are located on the left and right sides of the channel layer 103, respectively. In addition, a capacitance electrode (Cs) 111 is arranged above the source electrode 104 and the drain electrode 105. The capacitance electrode 111 corresponds to, for example, the retention capacitance element Cs in FIG. 2.

The capacitance electrode 111 is integrated with wiring 112, and the wiring 112 is connected to the gate electrode 101.

In the configuration of the TFT 100 shown in FIG. 3, the gate electrode 101, the source electrode 104, the drain electrode 105, the capacitance electrode 111, and the wiring 112 are made of metal. Since these constituents are made of metal, they form a region that does not allow the transmission of light.

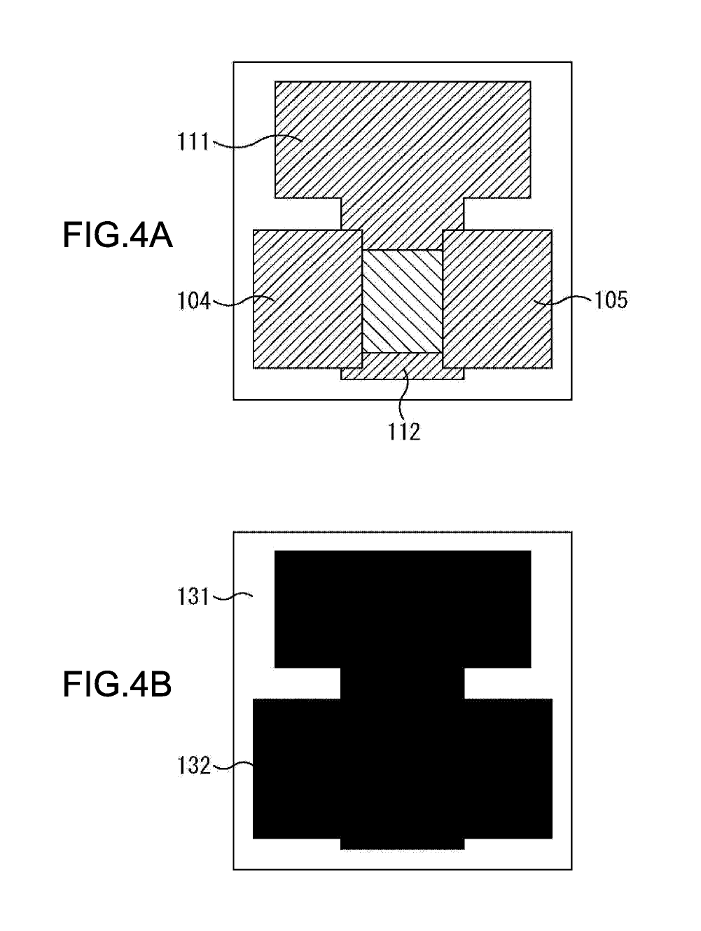

FIGS. 4A and 4B show a region that allows the transmission of light in the TFT 100 shown in FIG. 3. FIG. 4A is a plan view of the TFT 100 shown on the upper side of FIG. 3. FIG. 4B is a view showing both the region that allows the transmission of light and the region that does not allow the transmission of light when the light is applied to the TFT 100 from the above.

Referring to FIG. 4B, the region 131 that allows the transmission of light is smaller than the region 132 that does not allow the transmission of light. The region 132 that does not allow the transmission of light is an area at which the gate electrode 101, the source electrode 104, the drain electrode 105, the capacitance electrode 111, and the wiring 112 are located. As described above, the region 131 that allows the transmission of light is small if the gate electrode 101, the source electrode 104, the drain electrode 105, the capacitance electrode 111, and the wiring 112 are made of metal. Therefore, the TFT having such a configuration is not desirable as a TFT constituting a transparent display or the like.

(Conditions for Improving Transmittance)

Meanwhile, an organic EL display (OELD: Organic Electro Luminescence Display) is so structured as to easily constitute a transparent display higher in transmittance than a liquid crystal display. For example, a reason for it is that high transmittance may be realized with the use of transparent electrodes in a circuit since the organic EL layer of the organic EL display is almost transparent before its luminescence. In addition, another reason for it is that the organic EL display is allowed to output a clear image even if its backside is dark since the organic EL display is a self-luminous display.

The transmittance of the organic EL display is based on metal parts such as the wiring, the contact, and the capacitance electrode of a TFT. Basically, the luminescence layer of the organic EL display is almost transparent. Accordingly, the transmittance of the organic EL display may be improved with a decrease in the metal parts of TFT circuits.

However, since a great current flows in the wiring of the TFT, the resistance value of the wiring is increased if all the metal parts are replaced with transparent electrodes, which results in the likelihood that the normal operation of the display becomes difficult. In addition, the application of light to the TFT results in the likelihood that the characteristics of the TFT are changed. For example, an increase in Ioff and a shift in Vth are likely to occur.

Accordingly, it is desirable to employ a light shielding structure to prevent strong light from directly entering the TFT. Moreover, the characteristics of the TFT may be changed with the movement of oxygen when oxide semiconductors contact each other.

Thus, the capacitance electrode is mainly a part adjustable to improve light transmittance in the TFT used in a transparent display.

From the above reasons, it is desirable to use metal in the TFT for light-shielding in order to achieve a reliable transparent display and form the capacitance electrode, which occupies a large area of a pixel, with a transparent electrode in order to increase transmittance.

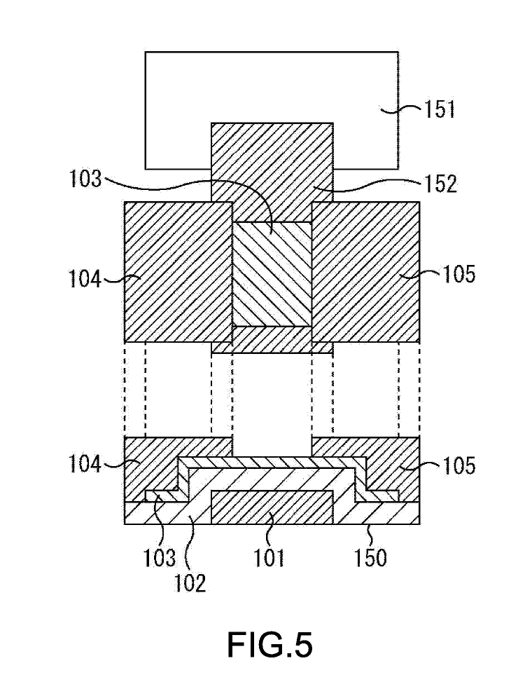

Hence, as shown in FIG. 5, a capacitance electrode is made of a transparent electrode. In FIG. 5, the cross-sectional view of a TFT 150 shown on the lower side is the same as that of the TFT 100 shown on the lower side of FIG. 3. In the TFT 150 shown in FIG. 5, the capacitance electrode 151 is made of a transparent material, and wiring 152 is made of metal.

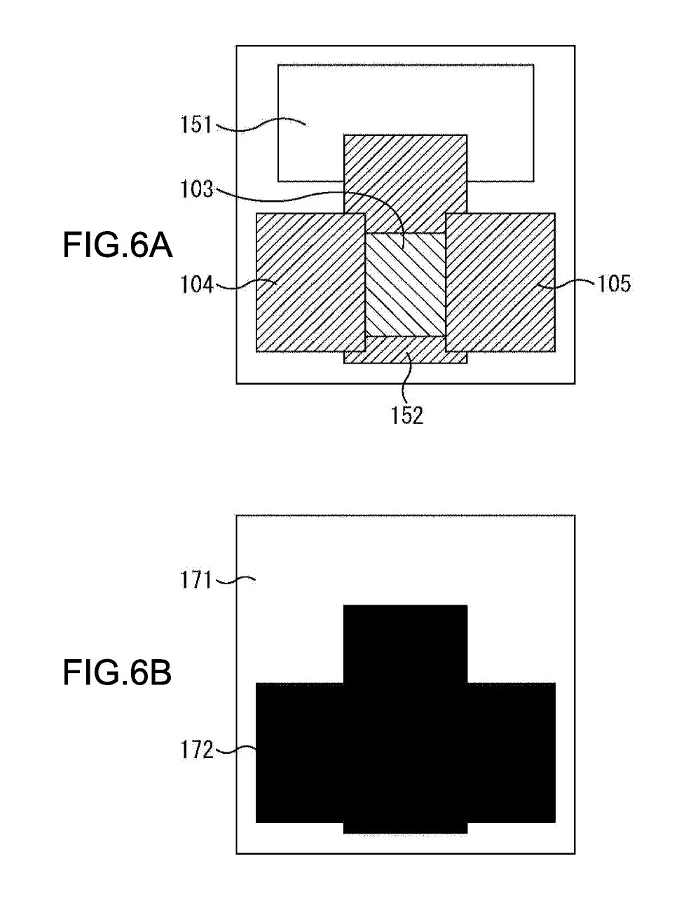

If the capacitance electrode 151 is made of a transparent material like this, a region that allows the transmission of light may be expanded as shown in FIGS. 6A and 6B. FIG. 6A is a plan view of the TFT 150 shown on the upper side of FIG. 5. FIG. 6B is a view showing both the region that allows the transmission of light and a region that does not allow the transmission of light when the light is applied to the TFT 150 from the above.

Referring to FIG. 6B, the region 171 that allows the transmission of light is smaller than the region 172 that does not allow the transmission of light but is larger than the region 131 that allows the transmission of light shown in FIG. 4B. The region 172 that does not allow the transmission of light is a region at which a gate electrode 101, a source electrode 104, a drain electrode 105, and wiring 152 are located. If the capacitance electrode 151 is made of a transparent material like this, the region 171 that allows the transmission of light may be expanded.

However, referring again to FIG. 5, the capacitance electrode 151 and the wiring 152 partially overlap each other. A loose connection or the like may be caused if the overlapped part is small, while transmittance may be reduced if it is large.

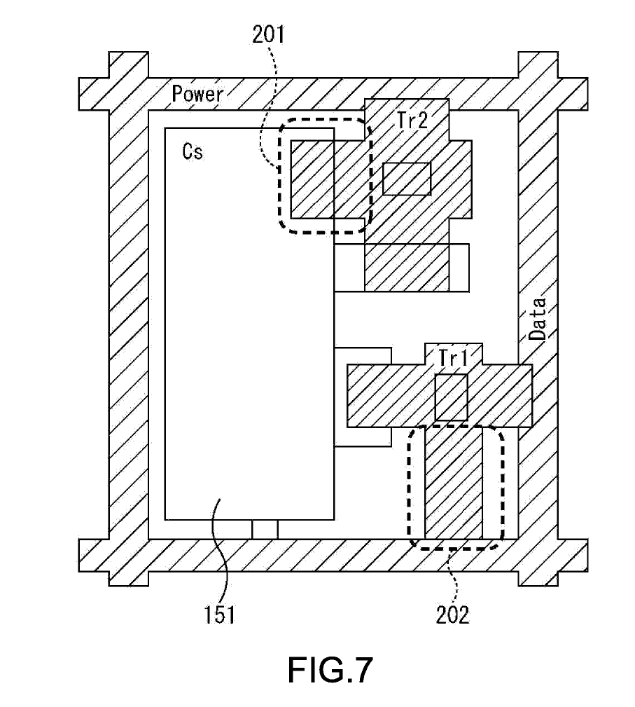

This matter will be described referring to FIG. 7. FIG. 7 shows an example of the circuit configuration of a pixel of an organic EL display. Referring to FIG. 7, it is desirable to install the wiring of both a writing transistor Tr1 and a driving transistor Tr2. If not only the above capacitance electrode 151 but also such desirably-installed wiring parts are made transparent, transmittance may be further improved.

In FIG. 7, parts at which an electrode made of a transparent material (hereinafter called a transparent electrode as occasion demands) and an electrode made of metal (hereinafter called a metal electrode as occasion demands) overlap each other are shown by dotted line frames. Regions 201 and 202 are areas at which the transparent electrode and the metal electrode contact each other. If the contact areas are increased to a greater extent, contact resistance caused when the different types of materials such as the transparent electrode and the metal electrode are joined together may be reduced.

Accordingly, from the viewpoint of reducing the contact resistance, it is desirable to increase the regions 201 and 202 at which the transparent electrode and the metal electrode overlap each other. However, if the metal region is increased, light transmittance is reduced. Therefore, in consideration of the transmittance, it is desirable to decrease the regions 201 and 202 at which the transparent electrode and the metal electrode overlap each other.

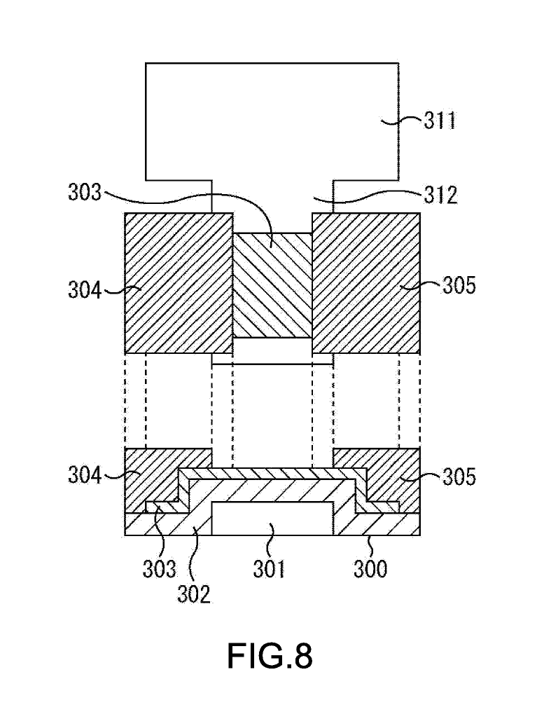

TFTs considering this matter will be described referring to FIG. 8 and the subsequent figures. In the TFTs that will be described referring to FIG. 8 and the subsequent figures, the following point is also taken into consideration. That is, it has been shown from an optical simulation that light shielding is allowed if gate metal has a width of about 3 μm from the end of a channel layer 103.

From this result, a metal electrode may be minimized. In this case, if a transparent electrode is expanded to a gate region, a lamination method is desirably changed depending on the constituent materials. Next, the constituent materials and the lamination method will be described.

### First Embodiment

As a first embodiment, a description will be given of an embodiment in which wiring or the like besides a capacitance electrode is made of a transparent material. In addition, a description will be given of an example of a case in which an amorphous-based material is used as a transparent material.

(First Part of First Embodiment)

FIG. 8 is a view showing the configuration of a TFT in a first part of the first embodiment. The upper side of FIG. 8 is a plan view of the TFT when seen from the above, and the lower side thereof is a cross-sectional view corresponding to the plan view.

Referring to the cross-sectional view of the TFT 300 shown on the lower side, a substrate is formed on the lowermost part of the TFT 300 and an insulation film is formed on the substrate although they are not shown in FIG. 8. In addition, a gate electrode 301 and a gate insulation film 302 are formed on the insulation film. A channel layer 303 is formed on the gate insulation film 302. A source electrode 304 is formed on the upper left side of the channel layer 303, and a drain electrode 305 is formed on the upper right side thereof. Such a configuration is the same as those of the TFT 100 shown in FIG. 3 and the TFT 150 shown in FIG. 5.

The substrate (not shown) is made of, for example, a material having transparency such as a glass. The insulation film is made of, for example, a-SiO₂. In the first part of the first embodiment, the gate electrode 301 is made of the same material as that of a capacitance electrode 311. The gate electrode 301 is made of, for example, IZO (Indium Tin Oxide), i.e., an amorphous-based material. In addition, the capacitance electrode 311 and wiring 312 are made of the same material as that of the gate electrode 301, for example, an amorphous-based material.

The channel layer 303 is made of, for example, InGaZnO₄ (Indium-Gallium-Zinc Oxide). Each of the source electrode 304 and the drain electrode 305 is made of, for example, molybdenum, aluminum, copper (Cu), titanium, ITO (Indium Tin Oxide), titanium oxide, or the like.

In the first part of the first embodiment, the capacitance electrode 311 and the gate electrode 301 are made of the same transparent material. In addition, the wiring 312 connecting the capacitance electrode 311 and the gate electrode 301 together is made of the same transparent material. That is, the capacitance electrode 311, the wiring 312, and the gate electrode 301 are integrated with each other by the transparent material.

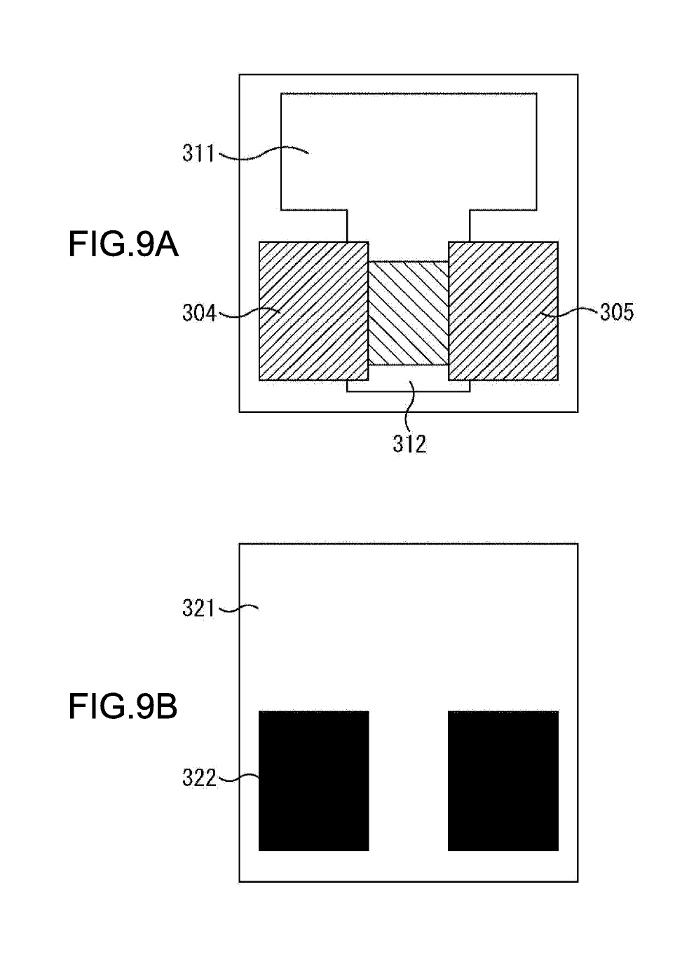

Since the above configuration increases a region that allows the transmission of light as shown in FIGS. 9A and 9B, it becomes possible to improve transmittance.

FIGS. 9A and 9B show the region that allows the transmission of light in the TFT 300 shown in FIG. 8. FIG. 9A is a plan view of the TFT 300 shown on the upper side of FIG. 8, and FIG. 9B is a view showing both the region that allows the transmission of light and a region that does not allow the transmission of light when the light is applied to the TFT 300 from the above.

If the channel layer 303 is made of a transparent material having light resistance, it also forms a layer that allows the transmission of light. FIG. 9B shows a case in which the channel layer 303 also allows the transmission of light. In other embodiments as well, a description will be given of an example of a case in which a channel layer 303 also allows the transmission of light.

Referring to FIG. 9B, the region 321 that allows the transmission of light is larger than the region 322 that does not allow the transmission of light. The region 322 that does not allow the transmission of light is an area at which the source electrode 304 and the drain electrode 305 are located. Since these constituents are made of metal, they form the region 322 that does not allow the transmission of light.

If the source electrode 304 and the drain electrode 305 are transparent electrodes made of a transparent material, the areas at which the source electrode 304 and the drain electrode 305 are located may also form the region 321 that allows the transmission of light.

However, if the source electrode 304 and the drain electrode 305 are made of the transparent electrodes of oxides, oxygen is exchanged between the oxides, which results in the likelihood that the characteristics are changed. Accordingly, the source electrode 304 and the drain electrode 305 are desirably made of metal. In the embodiment, the description will be continued on the assumption that the source electrode 304 and the drain electrode 305 are made of metal.

Note that it is also possible to employ a method for improving transmittance with the insertion of metal or a material other than an oxide as a thin film in at least an interface.

In other embodiments as well, a description will be given of an example in which a source electrode 304 and a drain electrode 305 are made of metal.

Note that if it is possible to use transparent electrodes whose characteristics are not changed, the source electrode 304 and the drain electrode 305 may also be made of transparent electrodes.

In the first part of the first embodiment, since the gate electrode 301, the capacitance electrode 311, and the wiring 312 are made of a transparent material as shown in FIG. 9A, these constituents form the region 321 that allows the transmission of light. Accordingly, the region 321 that allows the transmission of light shown in FIG. 9B is apparently larger than, for example, the region 131 that allows the transmission of light shown in FIG. 4B and the region 171 that allows the transmission of light shown in FIG. 6B.

Accordingly, the TFT 300 in the first part of the first embodiment makes it possible to improve transmittance.

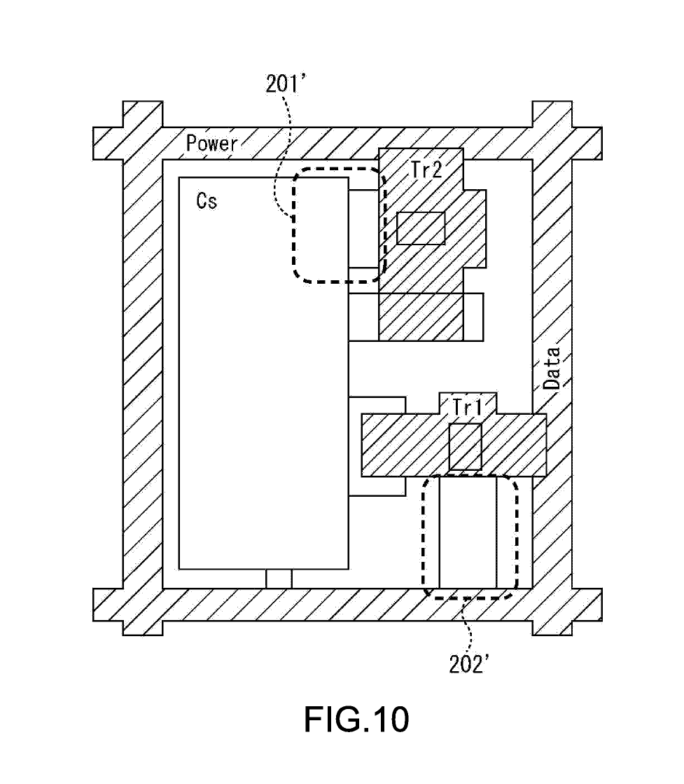

Moreover, referring to FIG. 10, a description will be given of a pixel configuration that may improve transmittance. FIG. 10 is a view showing an example of the circuit configuration of a pixel of an organic EL display to which the TFT 300 is applied. Referring to FIG. 10, it is desirable to install the wiring of both a writing transistor Tr1 and a driving transistor Tr2.

The regions 201 and 202 shown in FIG. 7 are denoted as regions 201′ and 202′ in FIG. 10, respectively. The regions 201 and 202 shown in FIG. 7 are the regions at which the transparent electrode and the metal electrode overlap each other.

Since the electrode (here, wiring 312) existing in the regions 201′ and 202′ is made of a transparent material in a case in which the TFT 300 is applied to the writing transistor Tr1 and the driving transistor Tr2, the regions 201′ and 202′ form regions that allow the transmission of light. Moreover, the regions 201′ and 202′ per se are not decreased, and areas at which a transparent electrode and a metal electrode contact each other are not decreased. Accordingly, contact resistance caused when the different types of materials such as the transparent electrode and the metal electrode are joined together may be reduced.

If the number of transistors increases, the number of the regions 201′ and 202′ also increases. Therefore, it is apparent that regions allowing the transmission of light in the display device 1 increase if such regions are made transparent.

Thus, the transmittance may be improved. In addition, since the gate electrode 301 per se is integrated with the wiring 312 by the same material, it becomes possible to prevent a loose connection or a disconnection from occurring between the gate electrode 301 and the wiring 312. Similarly, since the capacitance electrode 311 is integrated with the wiring 312 by the same material, it becomes possible to prevent a loose connection or a disconnection from occurring between the capacitance electrode 311 and the wiring 312.

(Second Part of First Embodiment)

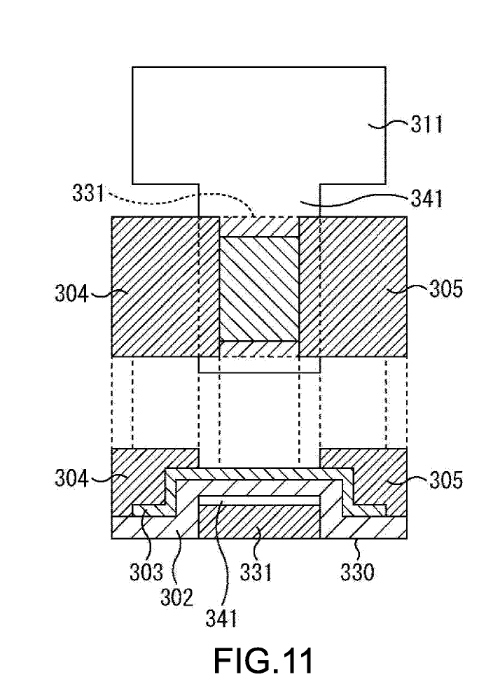

FIG. 11 is a view showing the configuration of a TFT in a second part of the first embodiment. The upper side of FIG. 11 is a plan view of the TFT when seen from the above, and the lower side thereof is a cross-sectional view corresponding to the plan view.

In the TFT 330 shown in FIG. 11, the same constituents as those of the TFT 300 shown in FIG. 8 are denoted by the same symbols, and their descriptions will be omitted.

The TFT 330 is different from the TFT 300 in that a gate electrode 331 is made of metal. With the metal gate electrode 331, it becomes possible to shield the stray light component of light or like reflected by a substrate (not shown).

In the TFT 330, wiring 341 is arranged between the gate electrode 331 and a gate insulation film 302. In other words, the wiring 341 is arranged so as to cover the upper part of the gate electrode 331. In addition, referring to the plan view shown on the upper side of FIG. 11, a part indicated by dotted lines at a central part shows the gate electrode 331. However, the wiring 341 is provided to be larger (longer in a downward direction in FIG. 11) than the gate electrode 331.

A capacitance electrode 311 and the wiring 341 are made of a transparent material, for example, an amorphous material such as IZO. On the other hand, the gate electrode 331 is made of metal. In this case, since the wiring 341 and the gate electrode 331 are made of the different materials, contact resistance or a loose connection may be caused between the wiring 341 and the gate electrode 331.

In the second part of the first embodiment, however, since the entire surface of the upper part of the gate electrode 331 contacts the wiring 341 as described above, it becomes possible to reduce the likelihood of the occurrence of a loose connection, separation, or the like and reduce contact resistance.

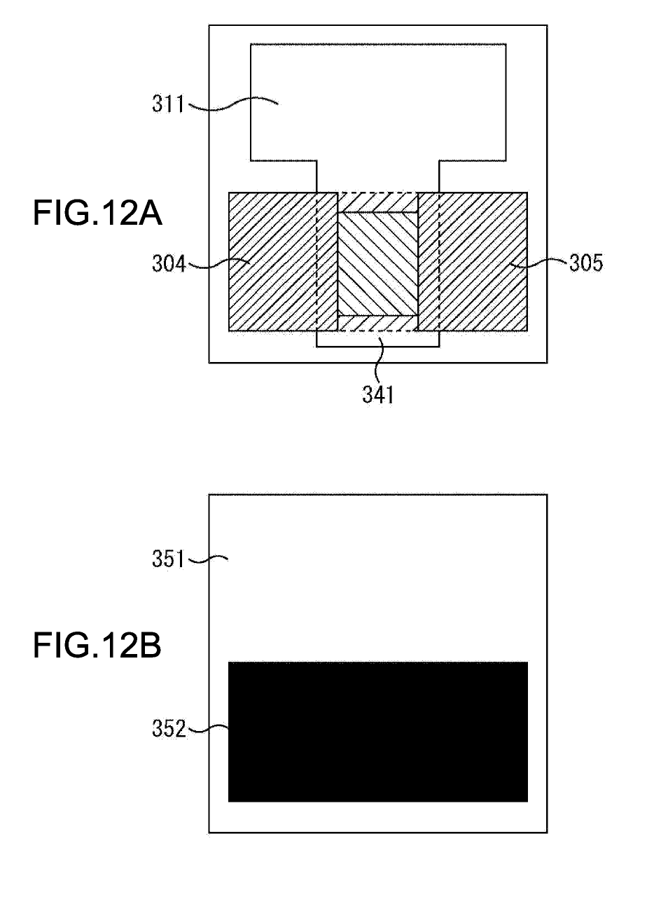

Since the above configuration increases a region that allows the transmission of light as shown in FIGS. 12A and 12B, it becomes possible to improve transmittance.

FIGS. 12A and 12B show the region that allows the transmission of light in the TFT 330 shown in FIG. 11. FIG. 12A is a plan view of the TFT 330 shown on the upper side of FIG. 11, and FIG. 12B is a view showing both the region that allows the transmission of light and a region that does not allow the transmission of light when the light is applied to the TFT 330 from the above.

Referring to FIG. 12B, the region 351 that allows the transmission of light is larger than the region 352 that does not allow the transmission of light. The region 352 that does not allow the transmission of light is an area at which the gate electrode 331, a source electrode 304, and a drain electrode 305 are located. Since these constituents are made of metal, they form the region 352 that does not allow the transmission of light.

In the second part of the first embodiment, however, since the capacitance electrode 311 and the wiring 341 are made of a transparent material, these constituents form the region 351 that allows the transmission of light. Accordingly, the region 351 that allows the transmission of light shown in FIG. 12B is apparently larger than, for example, the region 131 that allows the transmission of light shown in FIG. 4B and the region 171 that allows the transmission of light shown in FIG. 6B.

Accordingly, the TFT 330 in the second part of the first embodiment makes it also possible to improve transmittance.

(Third Part of First Embodiment)

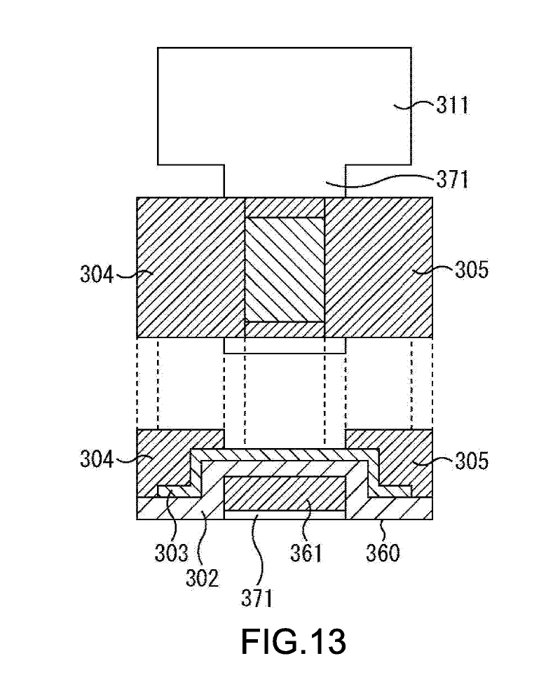

FIG. 13 is a view showing the configuration of a TFT in a third part of the first embodiment. The upper side of FIG. 13 is a plan view of the TFT when seen from the above, and the lower side thereof is a cross-sectional view corresponding to the plan view.

In the TFT 360 shown in FIG. 13, the same constituents as those of the TFT 330 shown in FIG. 11 are denoted by the same symbols, and their descriptions will be omitted. The TFT 360 is the same as the TFT 330 in that a gate electrode 361 is made of metal but is different from the TFT 330 in that wiring 371 is arranged beneath the gate electrode 361 as a layer.

With the metal gate electrode 331, it becomes possible to shield the stray light component of light or like reflected by a substrate (not shown) like the TFT 330 shown in FIG. 11.

In the TFT 360, the wiring 371 is arranged between the gate electrode 361 and the substrate (not shown). In other words, the wiring 371 is arranged so as to cover the lower part of the gate electrode 361. The wiring 371 is provided to be larger (longer in a downward direction in FIG. 13) than the gate electrode 361.

Accordingly, since the entire surface of the lower part of the gate electrode 361 contacts the wiring 371, it becomes possible to reduce the likelihood of the occurrence of a loose connection, separation, or the like and reduce contact resistance.

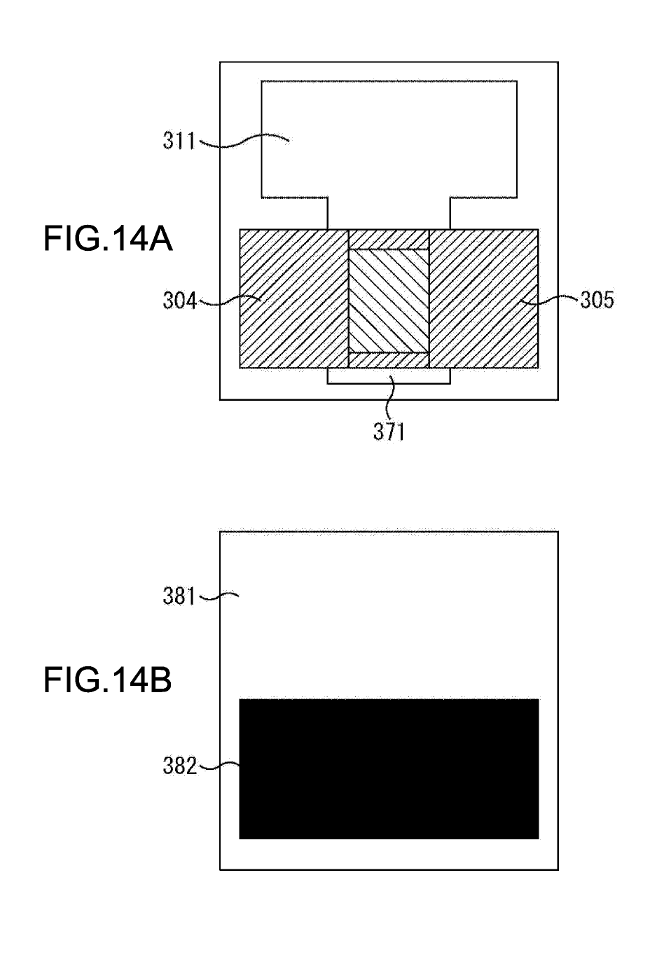

In addition, since the above configuration increases a region that allows the transmission of light as shown in FIGS. 14A and 14B, it becomes possible to improve transmittance.

FIGS. 14A and 14B show the region that allows the transmission of light in the TFT 360 shown in FIG. 13. FIG. 14A is a plan view of the TFT 360 shown on the upper side of FIG. 13, and FIG. 14B is a view showing both the region that allows the transmission of light and a region that does not allow the transmission of light when the light is applied to the TFT 360 from the above.

Referring to FIG. 14B, the region 381 that allows the transmission of light is larger than the region 382 that does not allow the transmission of light. The region 382 that does not allow the transmission of light is an area at which the gate electrode 361, a source electrode 304, and a drain electrode 305 are located. Since these constituents are made of metal, they form the region 382 that does not allow the transmission of light.

In the third part of the first embodiment, however, since a capacitance electrode 311 and the wiring 371 are made of a transparent material, these constituents form the region 381 that allows the transmission of light. Accordingly, the region 381 that allows the transmission of light shown in FIG. 14B is apparently larger than, for example, the region 131 that allows the transmission of light shown in FIG. 4B and the region 171 that allows the transmission of light shown in FIG. 6B.

Accordingly, the TFT 360 in the third part of the first embodiment makes it possible to improve transmittance.

As described above, according to the first embodiment, since the capacitance electrode and the wiring of the TFT are integrated with each other and made of a transparent material, it becomes possible to improve light transmittance and eliminate the likelihood of the occurrence of a loose connection or the like.

In addition, since the gate electrode is also integrated with the capacitance electrode and the wiring and made of a transparent material, it becomes possible to further improve light transmittance and eliminate the likelihood of the occurrence of a loose connection or the like.

In the examples of the first embodiment, the gate electrode 301 per se is made of amorphous, the wiring 341 made of amorphous is arranged on the gate electrode 331, and the wiring 371 made of amorphous is arranged beneath the gate electrode 361.

Since amorphous is excellent in flatness, it may be deposited without adversely affecting the flatness of other layers even if it is arranged between the above films. Accordingly, since amorphous is a suitable material for carrying out the first embodiment, the amorphous-based material is described in the first embodiment.

### Second Embodiment

A second embodiment is different from the first embodiment in that a crystal material is used as a transparent material instead of amorphous. Since other constituents are the same as those of the first embodiment, their descriptions will be omitted as occasion demands.

(First Part of Second Embodiment)

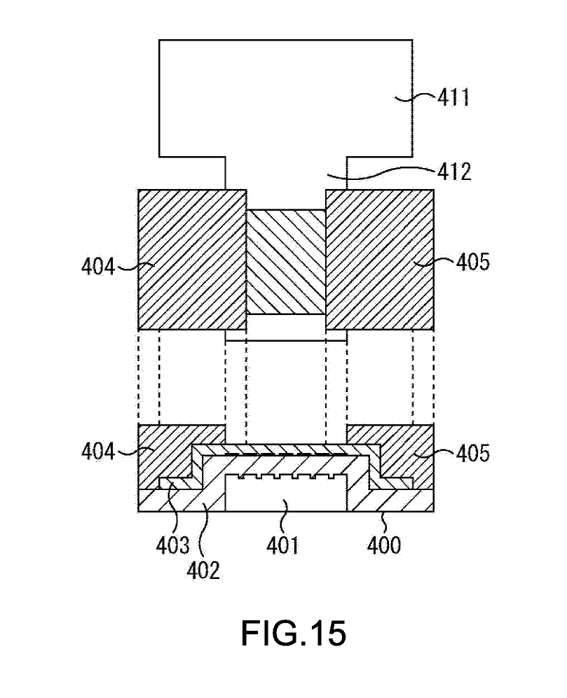

FIG. 15 is a view showing the configuration of a TFT in a first part of the second embodiment. The upper side of FIG. 15 is a plan view of the TFT when seen from the above, and the lower side thereof is a cross-sectional view corresponding to the plan view.

In the second embodiment as well, a substrate made of a transparent material such as glass is formed on the lowermost part of the TFT 400 and an insulation film is formed on the substrate like the configuration of the TFT of the first embodiment. In addition, a gate electrode 401 and a gate insulation film 402 are formed on the insulation film. A channel layer 403 is formed on the gate insulation film 402. A source electrode 404 is formed on the upper left side of the channel layer 403, and a drain electrode 405 is formed on the upper right side thereof.

In the first part of the second embodiment, a capacitance electrode 411 and the gate electrode 401 are made of the same transparent material. In addition, wiring 412 connecting the capacitance electrode 411 and the gate electrode 401 together is made of the same transparent material. That is, the capacitance electrode 411, the wiring 412, and the gate electrode 401 are integrated with each other by the transparent material.

As the transparent material constituting the capacitance electrode 411, the wiring 412, and the gate electrode 401, ITO (Indium Tin Oxide) that is a crystal material may be, for example, used. In the second embodiment, a description will be given of an example of a case in which a crystal material is used as the transparent material.

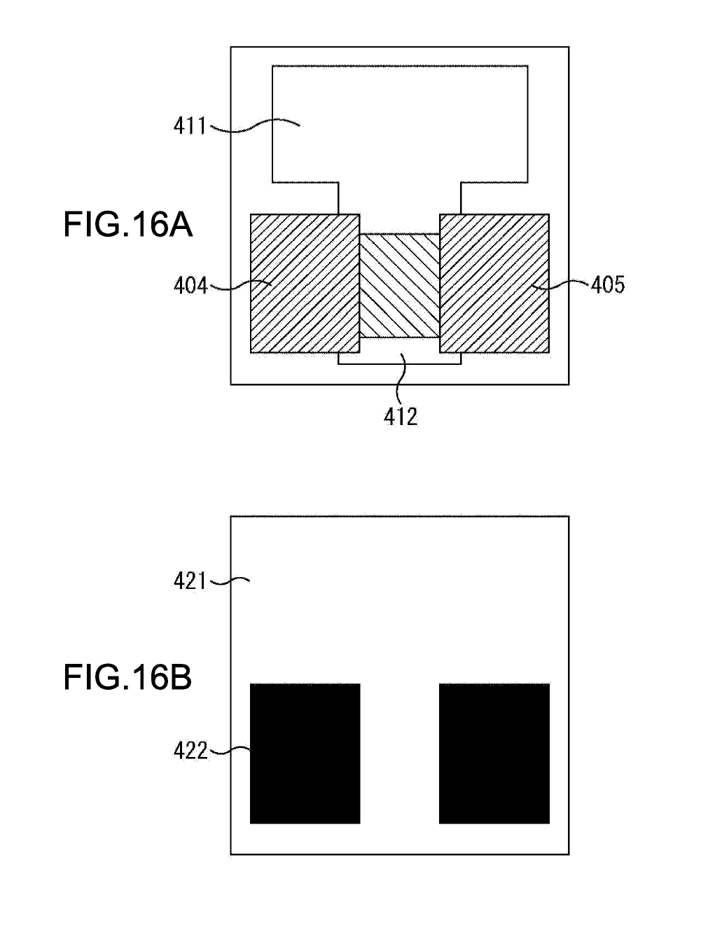

Since the above configuration increases a region that allows the transmission of light as shown in FIGS. 16A and 16B, it becomes possible to improve transmittance.

FIGS. 16A and 16B show the region that allows the transmission of light in the TFT 400 shown in FIG. 15. FIG. 16A is a plan view of the TFT 400 shown on the upper side of FIG. 15, and FIG. 16B is a view showing both the region that allows the transmission of light and a region that does not allow the transmission of light when the light is applied to the TFT 400 from the above.

Referring to FIG. 16B, the region 421 that allows the transmission of light is larger than the region 422 that does not allow the transmission of light. The region 422 that does not allow the transmission of light is an area at which the source electrode 404 and the drain electrode 405 are located. Since these constituents are made of metal, they form the region 422 that does not allow the transmission of light.

In the first part of the second embodiment, however, since the gate electrode 401, the capacitance electrode 411, and the wiring 412 are made of the transparent material, these constituents form the region 421 that allows the transmission of light. Accordingly, the region 421 that allows the transmission of light shown in FIG. 16B is apparently larger than, for example, the region 141 that allows the transmission of light shown in FIG. 4B and the region 171 that allows the transmission of light shown in FIG. 6B.

Accordingly, the TFT 400 in the first part of the second embodiment makes it possible to improve transmittance.

In addition, since the gate electrode 401 per se and the wiring 412 are integrated with each other by the same material, it becomes possible to prevent a loose connection or a disconnection from occurring between the gate electrode 401 and the wiring 412. Similarly, since the capacitance electrode 411 and the wiring 412 are integrated with each other by the same material, it becomes possible to prevent a loose connection or a disconnection from occurring between the capacitance electrode 411 and the wiring 412.

(Second Part of Second Embodiment)

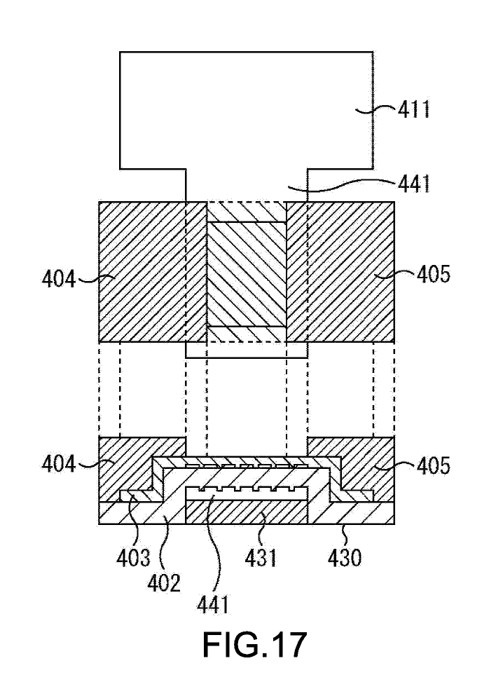

FIG. 17 is a view showing the configuration of a TFT in a second part of the second embodiment. The upper side of FIG. 17 is a plan view of the TFT when seen from the above, and the lower side thereof is a cross-sectional view corresponding to the plan view.

In the TFT 430 shown in FIG. 17, the same constituents as those of the TFT 400 shown in FIG. 15 are denoted by the same symbols, and their descriptions will be omitted.

The TFT 430 is different from the TFT 400 in that a gate electrode 431 is made of metal. With the metal gate electrode 431, it becomes possible to shield the stray light component of light or like reflected by a substrate (not shown).

In the TFT 430, wiring 441 is arranged between the gate electrode 431 and a gate insulation film 402. In other words, the wiring 441 is arranged so as to cover the upper part of the gate electrode 431. In addition, referring to the plan view shown on the upper side of FIG. 17, a part indicated by dotted lines at a central part shows the gate electrode 431. However, the wiring 441 is provided to be larger (longer in a downward direction in FIG. 17) than the gate electrode 431.

A capacitance electrode 411 and the wiring 441 are made of a transparent material, for example, a crystal material such as ITO. On the other hand, the gate electrode 431 is made of metal. Since the wiring 441 and the gate electrode 431 are made of the different materials, contact resistance is likely to be caused.

In the second part of the second embodiment, however, since the entire surface of the upper part of the gate electrode 431 may contact the wiring 441 as described above, it becomes possible to reduce the likelihood of the occurrence of a loose connection, separation, or the like and reduce contact resistance.

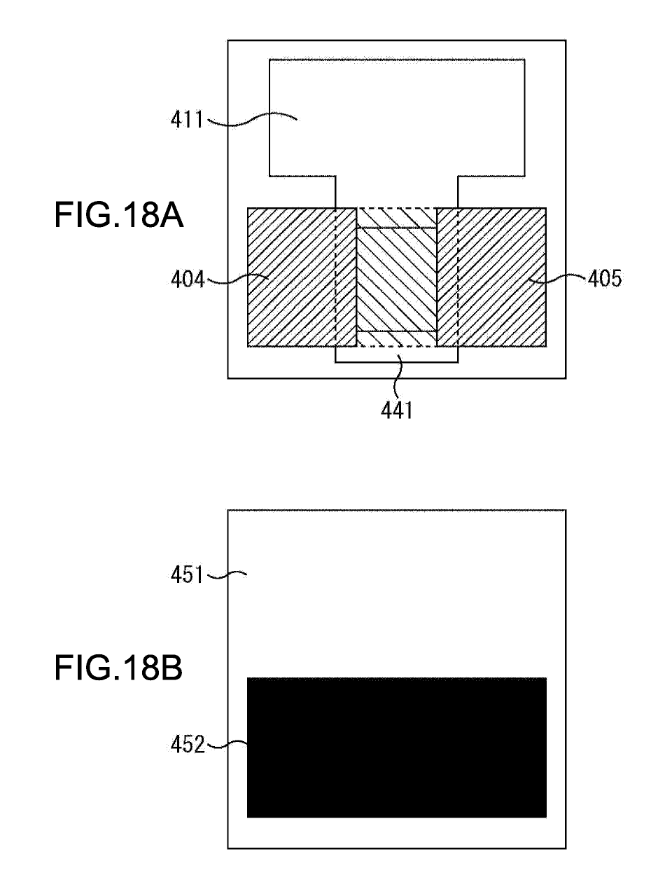

Since the above configuration increases a region that allows the transmission of light as shown in FIGS. 18A and 18B, it becomes possible to improve transmittance.

FIGS. 18A and 18B show the region that allows the transmission of light in the TFT 430 shown in FIG. 17. FIG. 18A is a plan view of the TFT 430 shown on the upper side of FIG. 17, and FIG. 18B is a view showing both the region that allows the transmission of light and a region that does not allow the transmission of light when the light is applied to the TFT 430 from the above.

Referring to FIG. 18B, the region 451 that allows the transmission of light is larger than the region 452 that does not allow the transmission of light. The region 452 that does not allow the transmission of light is an area at which the gate electrode 431, a source electrode 404, and a drain electrode 405 are located. Since these constituents are made of metal, they form the region 452 that does not allow the transmission of light.

In the second part of the second embodiment, however, since the capacitance electrode 411 and the wiring 441 are made of a transparent material, these constituents form the region 451 that allows the transmission of light. Accordingly, the region 451 that allows the transmission of light shown in FIG. 18B is apparently larger than, for example, the region 141 that allows the transmission of light shown in FIG. 4B and the region 171 that allows the transmission of light shown in FIG. 6B.

Accordingly, the TFT 430 in the second part of the second embodiment makes it also possible to improve transmittance.

(Third Part of Second Embodiment)

Meanwhile, the first and second parts of the second embodiment describe the example in which the gate electrode 401 per se is made of a crystal-based material and the example in which the wiring 441 made of a crystal-based material is arranged on the gate electrode 431, respectively.

If a transparent electrode such as the wiring 441 is formed on metal having light-shielding performance such as the gate electrode 431, a lithography mark is easily formed with the metal, which results in the advantage that a process is facilitated.

In the case of this structure, however, when amorphous is first deposited for processing and then crystallized by annealing, its front surface is likely to become rough. Reference will be made to the TFT 400 shown in FIG. 15 again. The TFT 400 shows a case in which the gate electrode 401 is made of a crystal-based material and the upper surface of the gate electrode 401 becomes rough. In FIG. 15, the roughness is indicated by irregularities. In addition, in the TFT 430 shown in FIG. 17 as well, the front surface of the wiring 441 arranged on the upper surface of the gate electrode 431 becomes rough, which results in the occurrence of irregularities.

When such a crystal-based material is used, the front surface becomes rough. If the gate insulation film 402 and the channel layer 403 are formed in a state in which the front surface becomes rough, the channel layer 403 is influenced as shown in FIG. 15 or FIG. 17. That is, irregularities may also remain at the interface of the channel layer 403.

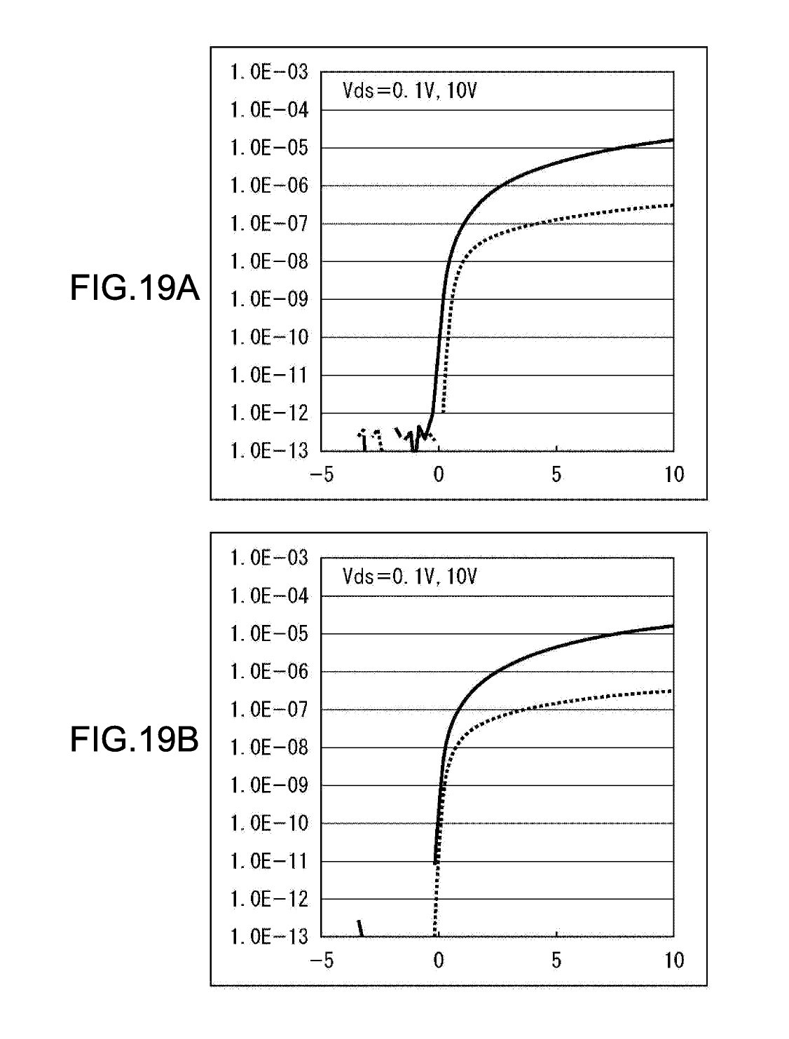

If the channel layer 403 becomes rough as described above, the characteristics of the TFT may be changed. FIGS. 19A and 19B are graphs for describing that the characteristics of the TFT are likely to be changed depending on whether the front surface becomes rough. FIGS. 19A and 19B show the Vg−Id characteristics of the TFT when the voltage Vds between Vs and Vd is set at 0.1 V and 10 V. In addition, FIG. 19A shows a case in which the front surface becomes rough, and FIG. 19B shows a case in which the front surface does not become rough.

From the example of FIG. 19A, it appears that a threshold voltage Vth is deviated when the voltage between Vs and Vd only changes. In addition, it appears that an initial motion is also unstable with its sharply fluctuating value. From the example of FIG. 19B, it appears that Vth is not deviated even when the voltage between Vs and Vd changes and that the initial motion is stable with its less fluctuating value if the front surface does not become rough.

Therefore, in the cases of the TFT 400 and the TFT 430 in which roughness is likely to occur, it is desirable that the TFT 400 and the TFT 430 absorb the roughness to prevent the channel layer 403 or the like from being influenced. For example, the thickness of the gate insulation film 402 may be increased to absorb the roughness on the gate electrode 401 or on the wiring 441 arranged on the gate electrode 431.

The TFT 400 and the TFT 430 are applicable to a device that allows a change in the characteristics of a TFT due to roughness, a device that desirably places priority on reducing light transmittance and contact resistance caused when the different types of materials are joined together, or the like.

If the following configuration is employed as a third part of the second embodiment, a TFT that has the same characteristics as those of the TFT free from roughness shown in FIG. 19B, improves transmittance, and reduces contact resistance or the like may be achieved. Hereinafter, the third part of the second embodiment will be described.

Note that since the first embodiment uses an amorphous-based material excellent in flatness as a transparent material, roughness influencing the channel layer 303 does not occur. Therefore, the TFT having the same characteristics as those of the TFT free from roughness shown in FIG. 19B may be achieved.

That is, the first embodiment describes an example in which an oxide semiconductor film excellent in flatness is deposited to form a transparent electrode on metal. An amorphous oxide conductive film is hardly crystallized even under heat treatment and may maintain its flatness.

In addition, it is desirable that irregularities, i.e., the roughness of the front surface be at least less than or equal to the film thickness of the channel layer 303. An example of a material satisfying such a condition is an InZnO film. An a-InZnO layer is not crystallized by annealing at about 300° C. close to the upper limit temperature of a process.

With such a material, the TFT whose characteristics are not degraded as shown in FIG. 19B may be achieved. As a result, the configuration suitable for improving transmittance and reducing contact resistance or the like as described in the first embodiment may be achieved.

Note that a material applicable as a transparent material in the first embodiment is not limited to a-IZO but a transparent conductive film excellent in flatness is available. Further, in a case in which a transparent material not excellent in flatness is used as in the second embodiment, a TFT less susceptible to roughness may be achieved with the following third part of the second embodiment.

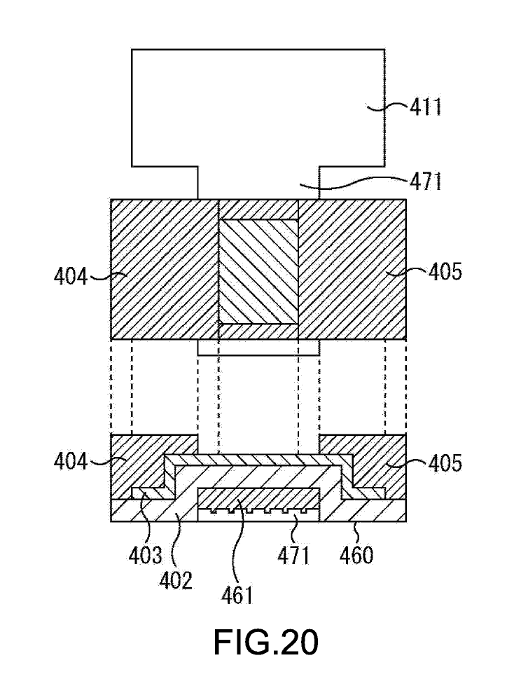

FIG. 20 is a view showing the configuration of a TFT in the third part of the second embodiment. The upper side of FIG. 20 is a plan view of the TFT when seen from the above, and the lower side thereof is a cross-sectional view corresponding to the plan view.

In the TFT 460 shown in FIG. 20, the same constituents as those of the TFT 430 shown in FIG. 17 are denoted by the same symbols, and their descriptions will be omitted.

The TFT 460 is the same as the TFT 430 in that a gate electrode 461 is made of metal but is different from the TFT 430 in that wiring 471 is arranged beneath the gate electrode 461 as a layer.

With the metal gate electrode 461, it becomes possible to shield the stray light component of light or like reflected by a substrate (not shown) like the TFT 430 shown in FIG. 17.

In the TFT 460, the wiring 471 is arranged between the gate electrode 461 and the substrate (not shown). In other words, the wiring 471 is arranged so as to cover the lower part of the gate electrode 461. The wiring 471 is provided to be larger (longer in a downward direction in FIG. 20) than the gate electrode 461.

A capacitance electrode 411 and the wiring 471 are made of a transparent material, for example, a crystal material such as ITO. On the other hand, the gate electrode 461 is made of metal. Since the wiring 471 and the gate electrode 461 are made of the different materials, contact resistance is likely to be caused.

In the third part of the second embodiment, however, since the entire surface of the lower part of the gate electrode 461 may contact the wiring 471 as described above, it becomes possible to reduce the likelihood of the occurrence of a loose connection, separation, or the like and reduce contact resistance.

In addition, since a transparent electrode is arranged beneath the metal, stepped cut or the like is less likely to occur even if the metal is not tapered.

In addition, the wiring 471 is arranged beneath the gate electrode 461. Therefore, even if the wiring 471 is made of a crystal-based material and roughness is likely to occur on the front surface of the wiring 471, the roughness may be absorbed by a metal film constituting the gate electrode 461.

In other words, since the metal gate electrode 461 is deposited on the wiring 471 made of a crystal-based material, it becomes possible to restore the flatness of the front surface of the wiring 471.

That is, as shown in FIG. 20, the metal of the gate electrode 461 gets in irregularities on the front surface of the wiring 471, whereby irregularities on the surface of the gate electrode 461 on the side of the gate insulation film 402 may be eliminated. Accordingly, it becomes possible to prevent roughness on the front surface of the wiring 471 from being influenced on the channel layer 403 provided on the upper side of the gate electrode 461.

The film thickness of the metal for restoring the flatness of the front surface, here, the film thickness of the gate electrode 461 is not limited but is desirably greater than or equal to about 100 nm. With the above configuration that restores the flatness of the front surface, it becomes possible to put the Id−Vg characteristics in a favorable state as shown in FIG. 19B.

In a case in which the transparent electrode (wiring 471) is arranged beneath the light-shielding metal (gate electrode 461) as in the TFT 460 shown in FIG. 20, the light-shielding metal is formed after the formation of the transparent electrode. Therefore, it is desirable to form a mark for increasing accuracy in lithography in advance.

If the mark is formed in advance, a TFT excellent in characteristics may be formed even with a material having front-surface roughness such as ITO.

The advantage of using a crystal-based material, for example, crystallized ITO as a transparent material is that a resistance value is small as a transparent electrode. It has been reported that the resistance of the crystallized ITO is small, i.e., 10-4 Ω·cm on average. That is, the crystallized ITO is an excellent material as a small-resistance transparent conductive film.

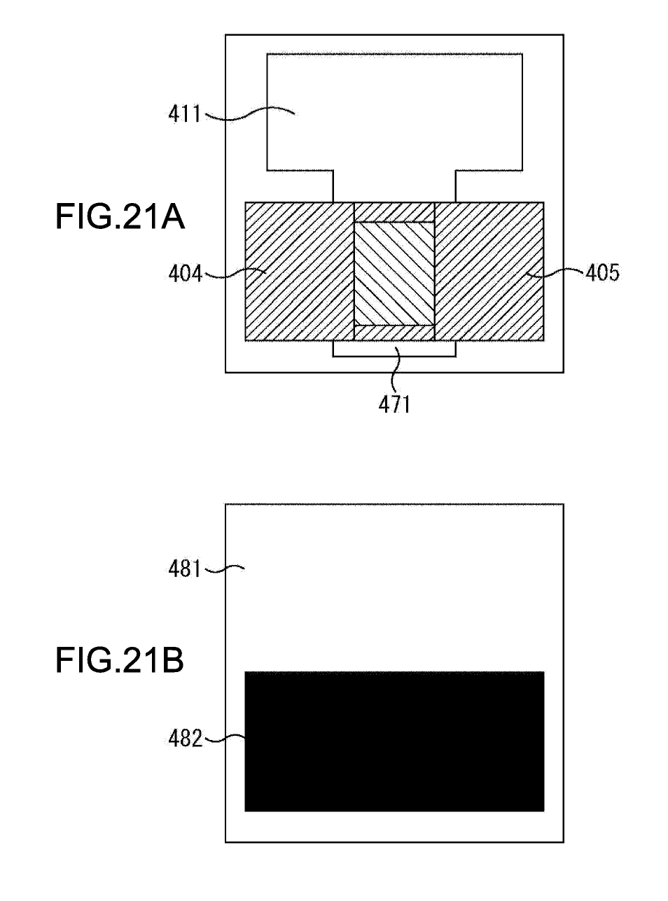

Since the above configuration increases a region that allows the transmission of light as shown in FIGS. 21A and 21B, it becomes possible to improve transmittance.

FIGS. 21A and 21B show the region that allows the transmission of light in the TFT 460 shown in FIG. 20. FIG. 21A is a plan view of the TFT 460 shown on the upper side of FIG. 20, and FIG. 21B is a view showing both the region that allows the transmission of light and a region that does not allow the transmission of light when the light is applied to the TFT 460 from the above.

Referring to FIG. 21B, the region 481 that allows the transmission of light is larger than the region 482 that does not allow the transmission of light. The region 482 that does not allow the transmission of light is an area at which the gate electrode 461, a source electrode 404, and a drain electrode 405 are located. Since these constituents are made of metal, they form the region 482 that does not allow the transmission of light.

In the third part of the second embodiment, however, since the capacitance electrode 411 and the wiring 471 are made of a transparent material, these constituents form the region 481 that allows the transmission of light. Accordingly, the region 481 that allows the transmission of light shown in FIG. 21B is apparently larger than, for example, the region 141 that allows the transmission of light shown in FIG. 4B and the region 171 that allows the transmission of light shown in FIG. 6B.

Accordingly, the TFT 460 in the third part of the second embodiment makes it also possible to improve transmittance.

As described above, according to the second embodiment, since the capacitance electrode and the wiring of the TFT are integrated with each other and made of a transparent material, it becomes possible to improve light transmittance and eliminate the likelihood of the occurrence of a loose connection or the like.

In addition, since the gate electrode is also integrated with the capacitance electrode and the wiring and made of a transparent material, it becomes possible to further improve light transmittance and eliminate the likelihood of the occurrence of a loose connection or the like.

The second embodiment describes the example in which the gate electrode 401 per se is made of a crystal-based material, the example in which the wiring 441 made of a crystal-based material is arranged on the gate electrode 431, and the example in which the wiring 471 made of a crystal-based material is arranged beneath the gate electrode 461.

A crystal-based material is not excellent in flatness and thus likely to have roughness on the front surface thereof but may achieve an improvement in transmittance, a reduction in contact resistance, or the like as described above. In addition, since a transparent electrode made of a crystal-based material is provided beneath metal as in the third part of the second embodiment, it becomes possible to reduce influence by roughness occurring on the front surface and achieve an improvement in transmittance, a reduction in contact resistance, or the like.

### Third Embodiment

As a third embodiment, a description will be given of the configurations of a TFT having a light-shielding film and a TFT having a plurality of gate electrodes. Here, although the third embodiment will show examples in which the light-shielding film or the gate electrodes is added to the TFT 460 described in the third part of the second embodiment, the configurations are also applicable to any of the first embodiment, the first part of the second embodiment, and the second part of the second embodiment.

(First Part of Third Embodiment)

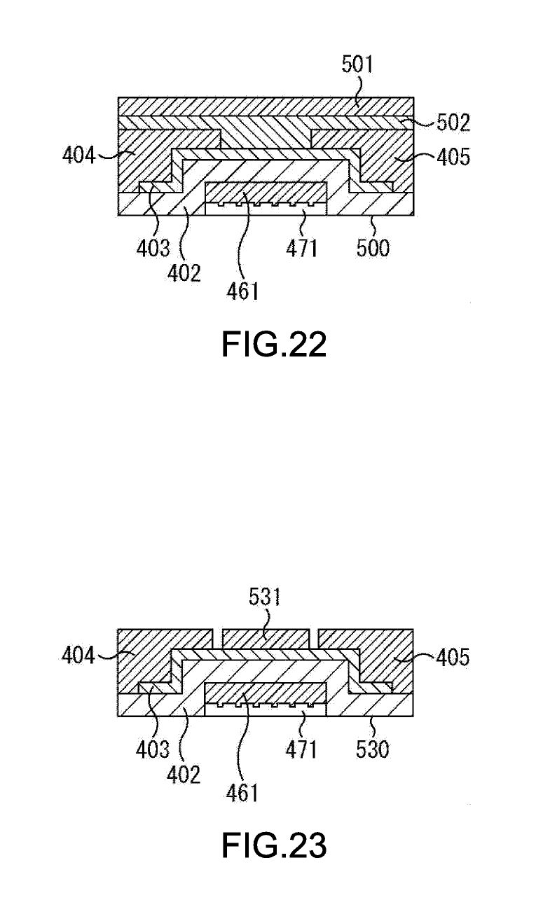

Since a TFT 500 shown in FIG. 22 has the same configuration as that of the TFT 460 shown in FIG. 20 except for the light-shielding film 501 added to the TFT 460 shown in FIG. 20, the description of the configuration will be omitted.

A gate electrode 461 has the function of shielding a stray light component from the lower part of the TFT 500 but may also shield a stray light component from the upper part thereof. Therefore, the light-shielding film 501 for shielding a stray light component from the upper part is provided on the upper side of a channel layer 403. A flattened film 502 is formed between the light-shielding film 501 and the channel layer 403.

In forming the light-shielding film 501 as described above, it is desirable that the light-shielding film 501 be formed as closest to a channel as possible in order to prevent light from hardly entering the channel layer 403.

The light-shielding film 501 may be made of metal. The light-shielding film 501 may be used not only as a light-shielding film but also as a gate electrode. That is, the TFT 500 may be of a dual gate structure having gate electrodes at the upper and lower parts thereof.

(Second Part of Third Embodiment)

In order to achieve both a dual gate structure and a light-shielding function, the structure of a TFT 530 shown in FIG. 23 may be used. In the structure of the TFT 530 shown in FIG. 23, a gate electrode 531 is provided right above the channel of a channel layer 403.

With the gate electrode 531 and a gate electrode 461 provided at the upper part and the lower part of the TFT 530, respectively, it is possible to achieve the structure that may effectively prevent stray light components from upper and lower directions from entering the channel layer 403.

According to the above embodiments, a high-transmittance transparent display may be achieved only with the use of minimum metal. Specifically, it has been confirmed by the present applicant that the present technology may achieve 50% or more transmittance.

In addition, since the contact area of a part at which the different types of materials such as metal and ITO overlap each other is increased, it becomes possible to reduce the occurrence of stepped cut, a loose connection, or the like and is effective for improving yields.

Moreover, since light is not applied to a device according to the structures of the above TFTs, it is also possible to improve the reliability of oxide semiconductor TFTs.

### APPLICATION EXAMPLES

Hereinafter, a description will be given of application examples of the above display device. The TFT to which the present technology is applied is applicable to the display device 1 as shown in FIG. 1. In addition, the display device 1 to which the present technology is applied is applicable to displays called transparent displays or the like that allow the visual recognition of their back surface side.

Moreover, the display device 1 to which the present technology is applied is applicable to electronic apparatuses in all fields such as TV sets, digital cameras, notebook computers, and mobile terminals like mobile phones.

In other words, the above display device is applicable to electronic apparatuses in all fields that display a video signal input from an outside or a video signal generated inside the electronic apparatuses as images or video.

Further, the display device to which the present technology is applied is applicable to displays called transparent displays or the like that allow the visual recognition of their back surface side. Examples taking advantage of such characteristics will be shown below.

(Application to Wall-Mounted Displays)

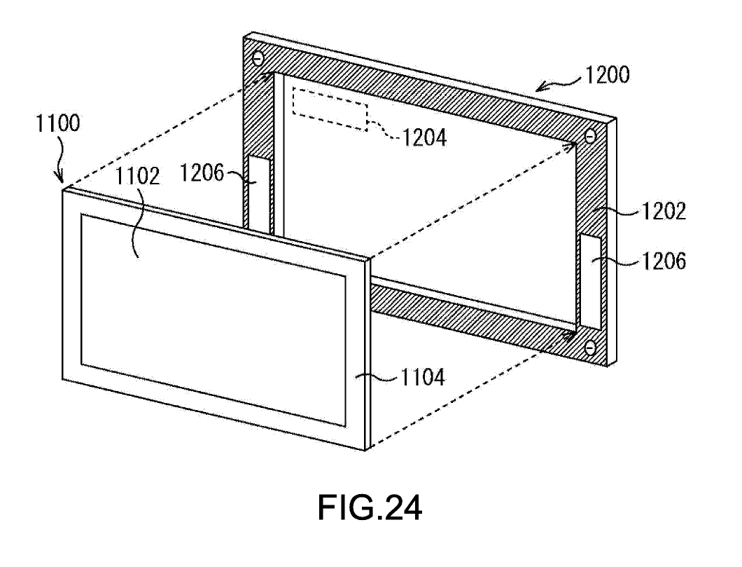

The display device to which the present technology is applied is applicable to wall-mounted displays. When the display device is applied to the wall-mounted displays, it may include a display unit 1100 and a base unit 1200 installed on a wall surface as shown in FIG. 24.

The present technology may be applied to the display unit 1100 to form a transparent display. The base unit 1200 is made of a peripheral portion 1202, a signal input/output terminal 1204, and an audio output portion 1206.

In the example of FIG. 24, the outer periphery of the display unit 1100 is fitted in and fixed to the inner periphery of the peripheral portion 1202 forming the base unit 1200. On this occasion, the signal input/output terminal 1102 of the display unit 1100 and the signal input/output terminal 1204 of the base unit 1200 are connected to each other.

The display unit 1100 is a transparent display and installed in the base unit 1200. When video is not displayed on the display unit 1100, the display unit 1100 allows the visual recognition of a wall surface on the back surface side thereof.

For example, assuming that the periphery of the display unit 1100 is a picture frame, a picture is displayed inside the base unit 1200. When an image is not displayed on the display unit 1100, the display unit 1100 allows the visual recognition of the picture displayed on the wall surface as if it were displayed inside the picture frame. Meanwhile, when an image (video) is displayed on the display unit 1100, the display unit 1100 is allowed to function as a display equivalent to a television receiver or the like.

(Application Example to Mobile Terminals)

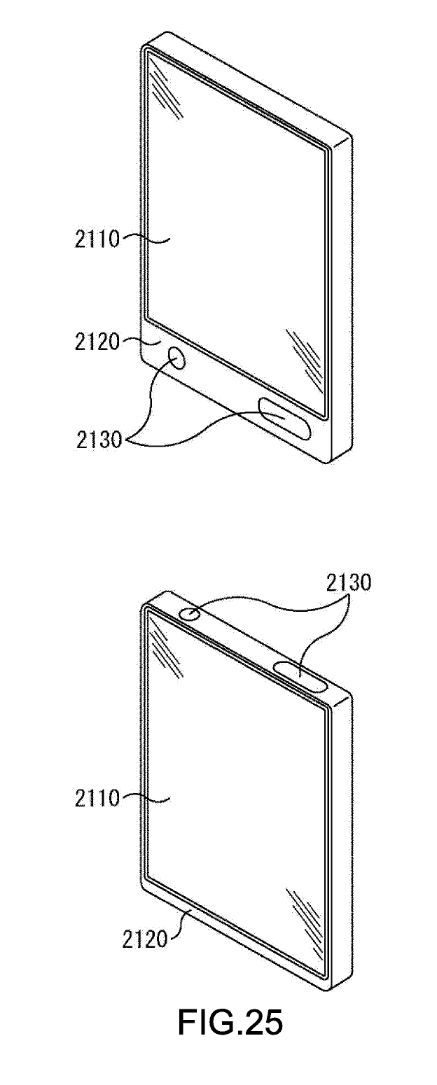

The display device to which the present technology is applied is applicable to mobile terminals called smart phones or the like. FIG. 25 shows the appearance of a smart phone. The smart phone has, for example, a display unit 2110, a non-display unit (housing) 2120, and an operation unit 2130. The operation unit 2130 may be provided at the front surface of the non-display unit 2120 as shown on the upper side of FIG. 25 or may be provided at the upper surface thereof as shown on the lower side of FIG. 25.

When the display device to which the present technology is applied is applied to the smart phone shown in FIG. 25, it is applicable to the display unit 2110.

In recent years, AR (Augmented Reality) technology has been frequently discussed. The AR technology features the presentation of a virtual object as additional information (electronic information) in combination with (a part of) real environment and is contrasted with virtual reality (VR).

In the AR technology, it is general that an explanation or related information on a specific object in real environment is presented near the actual object as an explanation object. As a method for enhancing reality (sense of reality) in the AR, a transparent display may be used. Using the smart phone shown in FIG. 25, a user may visually recognize additional information displayed on the display unit 2110 and enjoy augmented reality while visually recognizing real environment.

(Application to in-Vehicle Displays)

The display device to which the present technology is applied is also applicable to displays for navigation systems mounted on automobiles or the like.

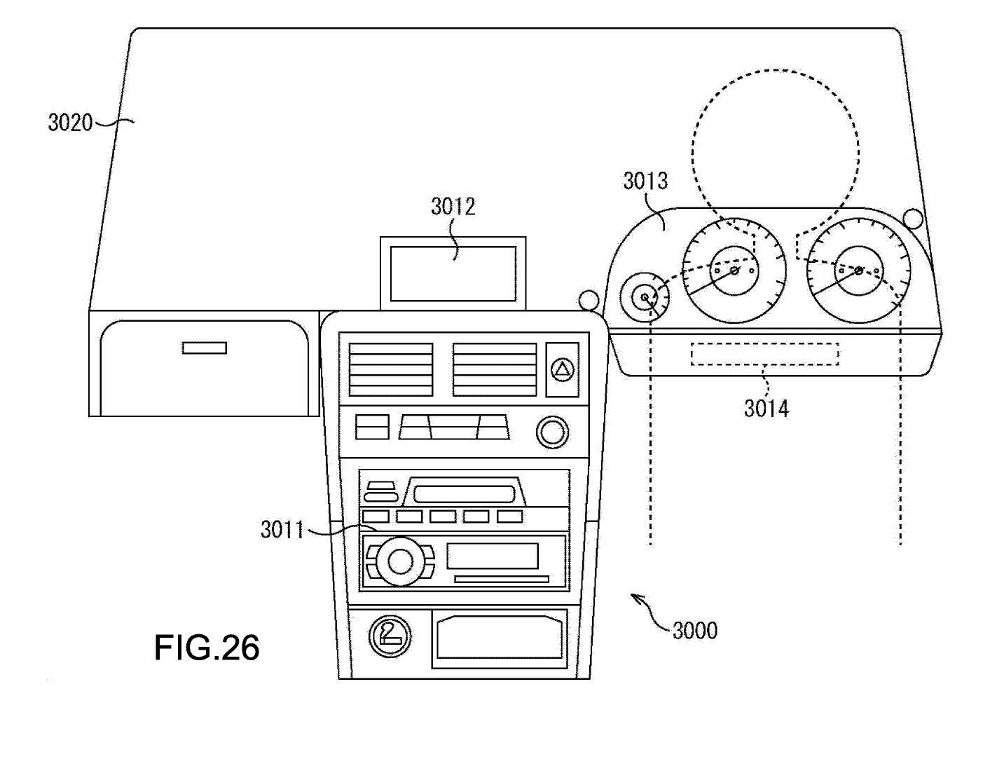

FIG. 26 shows the periphery of the driver's seat of an automobile including a navigation system having the display device to which the present technology is applied. In front of the driver's seat of the automobile, a windshield 3020 as a transparent body is provided on the upper side of an instrument panel 3000.

In addition, a navigation system main body 3011 is installed on the central lower side of the instrument panel 3000, and a liquid crystal display 3012 that displays navigation information is mounted over the navigation system main body 3011.

Moreover, a meter panel 3013 is provided on the seat side of a driver as a user indicated by dotted lines in FIG. 26. Further, on the lower back side of the meter panel 3013, a projection unit that projects video on the windshield 3020 or a display unit 3014 that serves as a display mechanism is mounted.

Generally, in the navigation system having such a configuration, navigation information such as a recommended route or the like searched by the navigation system main body 3011 is displayed on the liquid crystal display 3012. In addition, in this mode, it becomes possible to display navigation information on the windshield 3020 using the display unit 3014 as occasion demands.

The display device (transparent display) to which the present technology is applied may be embedded in a part of the windshield 3020 to display navigation information. With the transparent display, it becomes possible to construct a system that allows a user to confirm navigation information while seeing road conditions or the like.

(Application to Train Windows)

The display device to which the present technology is applied is applicable to displays that present information to users riding on movable bodies such as trains.

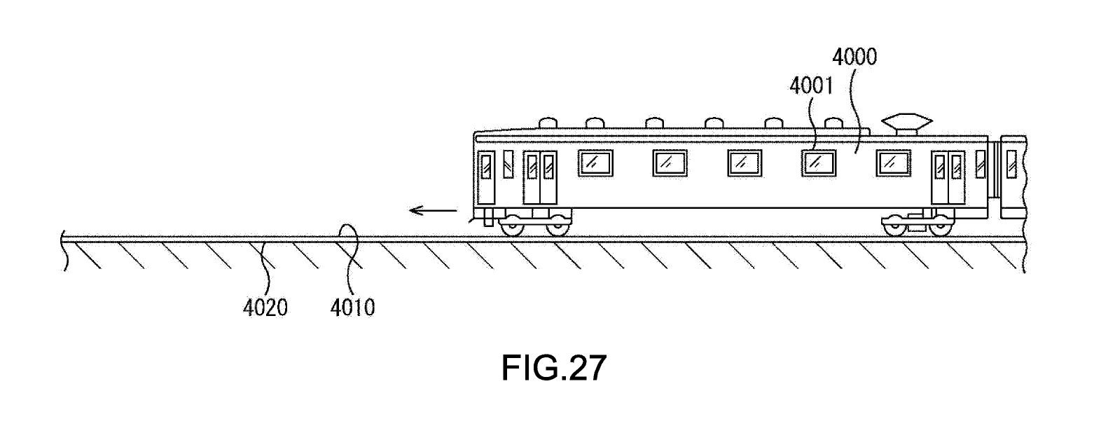

FIG. 27 is a view showing the configuration of an example of a movable body having the display device to which the present technology is applied. As shown in FIG. 27, the movable body is one that runs on a running path 4020, on which a rail 4010 is laid, while carrying persons, i.e., a train 4000 in this example.

The train 4000 has a window 4001, and a passenger is allowed to see outside scenery or the like through the window 4001. A transparent display as the display device to which the present technology is applied may be provided in the window 4001 to display information.

Thus, the application range of the present technology is wide and is not limited to the above application range.

In addition, the system in the specification represents an entire device made of a plurality of devices.

Note that the effects described in the specification are only for illustration and other effects may be produced.

Note that the embodiments of the present technology are not limited to the above embodiments but may be modified in various ways within the spirit of the present technology.

Note that the present technology may also employ the following configurations.

(1) A display device, including:

a display element; and

a transistor configured to drive the display element,

the transistor having
a channel layer,
a gate electrode laminated under the channel layer, and
wiring connecting the gate electrode and a capacitance electrode together,
the capacitance electrode and the wiring being made of at least a transparent material.

(2) The display device according to (1), in which

the gate electrode, the capacitance electrode, and the wiring are made of the same transparent material.

(3) The display device according to (2), in which

the transparent material includes an amorphous-based material.

(4) The display device according to (2), in which

the transparent material includes a crystal-based material.

(5) The display device according to any one of (1), (3), and (4), in which

the gate electrode is made of metal,

the capacitance electrode and the wiring are made of the transparent material, and

the wiring is laminated between the gate electrode and the channel layer.

(6) The display device according to (5), in which

the wiring is connected to the gate electrode so as to cover an upper surface of the gate electrode.

(7) The display device according to any one of (1), (3), and (4), in which

the gate electrode is made of metal,

the capacitance electrode and the wiring are made of the transparent material, and

the wiring is formed on a lower surface of the gate electrode.

(8) The display device according to (7), in which

the wiring is connected to the gate electrode so as to cover the lower surface of the gate electrode.

(9) The display device according to any one of (1) to (8), in which

a light-shielding film is laminated on an upper side of the channel layer.

(10) The display device according to any one of (1) to (8), further including:

a gate electrode on an upper side of the channel layer.

(11) The display device according to any one of (1) to (10), in which

the channel layer is made of a transparent material.

(12) The display device according to any one of (1) to (11), in which

the display element includes an organic EL (Electro Luminescence) element.

(13) The display device according to any one of (1) to (12), in which

the transistor includes a TFT (Thin Film Transistor).

(14) An electronic apparatus, including:

a display element having
a display element,
a transistor configured to drive the display element,
the transistor having
   a channel layer,
   a gate electrode laminated under the channel layer, and
   wiring connecting the gate electrode and a capacitance electrode together,
   the capacitance electrode and the wiring being made of at least a transparent material.

What is claimed is:

1. A display device, comprising:
a display element; and
a transistor configured to drive the display element,
the transistor having
a channel layer,
a gate electrode laminated under the channel layer, and
wiring connecting the gate electrode and a capacitance electrode together,
the capacitance electrode and the wiring being made of at least a transparent material.

2. The display device according to claim 1, wherein
the gate electrode, the capacitance electrode, and the wiring are made of the same transparent material.

3. The display device according to claim 2, wherein
the transparent material includes an amorphous-based material.

4. The display device according to claim 2, wherein
the transparent material includes a crystal-based material.

5. The display device according to claim 1, wherein
the gate electrode is made of metal,
the capacitance electrode and the wiring are made of the transparent material, and
the wiring is laminated between the gate electrode and the channel layer.

6. The display device according to claim 5, wherein
the wiring is connected to the gate electrode so as to cover an upper surface of the gate electrode.

7. The display device according to claim 1, wherein
the gate electrode is made of metal,
the capacitance electrode and the wiring are made of the transparent material, and
the wiring is formed on a lower surface of the gate electrode.

8. The display device according to claim 7, wherein
the wiring is connected to the gate electrode so as to cover the lower surface of the gate electrode.

9. The display device according to claim 1, wherein
a light-shielding film is laminated on an upper side of the channel layer.

10. The display device according to claim 1, further comprising:
a gate electrode on an upper side of the channel layer.

11. The display device according to claim 1, wherein
the channel layer is made of a transparent material.

12. The display device according to claim 1, wherein
the display element includes an organic EL (Electro Luminescence) element.

13. The display device according to claim 1, wherein
the transistor includes a TFT (Thin Film Transistor).

14. An electronic apparatus, comprising:
a display element including
a display element,
a transistor configured to drive the display element,
the transistor having
a channel layer,
a gate electrode laminated under the channel layer, and
wiring connecting the gate electrode and a capacitance electrode together,
the capacitance electrode and the wiring being made of at least a transparent material.
